(19) United States
(12) Patent Application Publication
(10) Pub. No.: US 2025/0251451 A1
(43) Pub. Date: Aug. 7, 2025

(54) MEMS hot switch testing system

(71) Applicant: Menlo Microsystems, Inc., Irvine, CA (US)

(72) Inventors: Maxwell Connor de Feijter, Menands, NY (US); Chris Nassar, Hudson, NY (US)

(21) Appl. No.: 18/430,187

(22) Filed: Feb. 1, 2024

(51) Int. Cl. G01R 31/327

(52) U.S. Cl. CPC G01R 31/3272

(57) ABSTRACT

Embodiments disclose a system for testing a micro-electromechanical-system (MEMS) switch under hot switching conditions. The system includes a processor, and an instruction memory with computer code instructions stored thereon, configured to cause the system cyclically open and close while a voltage is applied to at least one contact of the MEMS switch. The system measures and stores in a characteristic memory one or more characteristic values associated with the MEMS switch during the cyclical opening and closing. The system records an operational status of the MEMS switch during one or more cycles of the MEMS switch being opened and closed. The operational status of the MEMS switch is either an operational state or a failure state. The system then calculates a life expectancy of the MEMS switch utilizing the measured characteristic values associated with the MEMS switch and the operational status of the MEMS switch.

### BACKGROUND

Microelectromechanical switches (MEMS) are an emerging technology for high power radio frequency (RF) and microwave switch applications. These devices offer the same power handling and RF performance of an electromechanical (EM) relay with the size, weight, reliability and speed of a solid-state device. However, testing the performance of these devices is an underexplored area of this emerging technology. One aspect of MEMS switch performance is switching while these devices have a voltage applied to them, i.e., when they are “hot,” since hot switching is known to have detrimental effects such as degraded switch contacts. Although the occurrence of hot switching may be limited under normal operating conditions, it would be helpful to understand the effects of extensive hot switching on switch performance. A test that characterizes the long-term performance of a MEMS switch under hot switching conditions is therefore desired.

### SUMMARY

Disclosed herein is a system for testing a micro-electromechanical-system (MEMS) switch under hot switching conditions. The system includes a processor and an instruction memory with computer code instructions stored thereon. The processor is configured to execute the computer code instructions in the instruction memory to cause the MEMS switch to cyclically open and close while a voltage is applied to at least one contact of the MEMS switch and/or while a current is flowing through the MEMS switch. The system then measures and stores in a characteristic memory one or more characteristic values associated with the MEMS switch during the cyclical opening and closing. The system then records an operational status of the MEMS switch during one or more cycles of the MEMS switch being opened and closed, the operational status of the MEMS switch being either an operational state or a failure state. The system then calculates a life expectancy of the MEMS switch utilizing the characteristic values associated with the MEMS switch and the operational status of the MEMS switch.

According to an embodiment, the one or more characteristic values includes a pull-in voltage, a pull-off voltage, an on-resistance, and/or an off-resistance of the MEMS switch.

Another embodiment includes a test circuit that hosts a MEMS switch and is operatively coupled to the processor to receive one or more control signals from the processor for controlling the MEMS switch that provides one or more characteristic values associated with the MEMS switch to the processor.

Another embodiment includes a test circuit that: (i) hosts the MEMS switch, and (ii) is operatively coupled to the processor to receive one or more control signals from the processor for controlling the MEMS switch, provides one or more characteristic values associated with the MEMS switch to the processor.

In another embodiment, the material composition and a layout geometry of the test circuit is configured to maintain parasitic inductance below a predetermined inductance threshold and maintain parasitic capacitance below a predetermined capacitance threshold.

In another embodiment, the material composition and layout geometry of the test circuit further provides appropriate spacing and/or insulation to reduce parasitic inductance and/or parasitic capacitance.

In another embodiment, the computer code instructions are further configured to cause the system to measure the one or more characteristic values prior to the MEMS switch being cyclically opened and closed and/or after the operational status indicates a failure state of the MEMS switch.

In an embodiment the failure state is determined by any one of the MEMS switches under test failing to open or failing to close, any one of a parametric value being outside of a manufacturer specified value for the MEMS switch, or any combination thereof.

In an embodiment, the operational status includes the MEMS switch being open when a control signal indicates that the MEMS switch should be open, and the MEMS switch being closed when a control signal indicates that the MEMS switch should be closed. The operational status further includes an on-resistance of the MEMS switch being within a specified range when the control signal indicates that the MEMS switch should be closed, and the on-resistance of the MEMS switch being within a specified range when the control signal indicates that the MEMS switch should be open.

In an embodiment, the cyclically opening and closing the MEMS switch includes cycling the MEMS switch through a predetermined number of open-to-close and close-to-open cycles.

In an embodiment, the system is configured to measure, test, and record repeatedly until the MEMS switch indicates a failure state.

In an embodiment, if the operational status is not met, the system returns a failure state.

In an embodiment, wherein the voltage is non-zero.

According to an embodiment, the computer code instructions are further configured to cause the system to apply a known first voltage through a load resister to an input of the MEMS switch, measure a second voltage at the input of the MEMS switch, compare a reference voltage that is greater than zero volts and less than the known first voltage to the second voltage, and indicate that the MEMS switch is open when a comparison shows the second voltage is above the known first voltage, or the MEMS switch is closed when the second voltage is below the first known voltage, based on a comparison of the known first voltage and the second voltage.

In an embodiment, the system is further configured to adjust a frequency of the cyclical open and cyclical closing of the MEMS switch based on electrical characteristics of an electrical load.

In an embodiment, the system is further configured to adjust the duty cycle of the cyclical open and cyclical close of the MEMS switch based on electrical characteristics of an electrical load.

Another embodiment includes a reed relay matrix configured to selectively couple one or more test instruments to the MEMS switch.

In an embodiment, the instruction memory and the characteristic memory share a common physical memory space.

An embodiment includes a system for testing a micro-electro-mechanical-system (MEMS) switch under hot switching conditions. The system includes a control circuit configured to cause the MEMS switch to be cyclically opened and closed while a voltage is applied to at least one contact of the MEMS switch. The system also includes a measurement device configured to measure at least one characteristic of the MEMS switch, and a recording device configured to record the at least one characteristic of the MEMS switch at one or more times while the control circuit causes the MEMS switch to be cyclically opened and closed.

An embodiment includes a method of testing a micro-electromechanical-system (MEMS) switch under hot switching conditions. The method causes the MEMS switch to cyclically open and close while a voltage is applied to at least one contact of the MEMS switch. The method then measures and stores, in a characteristic memory, one or more characteristic values associated with the MEMS switch during the cyclical open and closing. The method then records an operational status of the MEMS switch during one or more cycles of the MEMS switch being opened and closed, wherein the operational status of the MEMS switch is either an operational state or a failure state. Lastly, the method calculates a life expectancy of the MEMS switch utilizing the measured characteristic values associated with the MEMS switch and the operational status of the MEMS switch.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The foregoing will be apparent from the following more particular description of example embodiments, as illustrated in the accompanying drawings in which like reference characters refer to the same parts throughout the different views. The drawings are not necessarily to scale, emphasis instead being placed upon illustrating embodiments.

FIG. 1A shows a block diagram of an example MEMS hot-switch testing system, according to an embodiment.

FIG. 1B shows a flow diagram of example operation of a MEMS hot-switch testing system, according to an embodiment.

FIG. 1C shows another example embodiment of a MEMS hot-switch testing system

FIG. 2 shows a schematic diagram of the heartbeat functionality of a MEMS hot-switch testing system, according to an embodiment.

FIG. 3 illustrates a daughter card layout showing how parasitic capacitance is reduced in the circuit design.

FIG. 4 shows a 3D rendering of a daughter card illustrating the placement of load components, such as load capacitors and load resistors, relative to the device under test.

FIGS. 5A and 5B show oscilloscope readouts comparing the waveform of the MEMS device opening to the waveform of the device closing, according to an embodiment.

FIG. 6 is a diagram of an example internal structure of a processing system that may be used to implement one or more of the embodiments.

### DETAILED DESCRIPTION

A description of example embodiments follows.

While example embodiments have been particularly shown and described, it will be understood by those skilled in the art that various changes in form and details may be made therein without departing from the scope of the embodiments encompassed by the appended claims.

Microelectromechanical switches (MEMS) are an emerging technology for high power radio frequency (RF) and microwave switch applications. Unfortunately, there exists little data on the effect of opening and/or closing a MEMS switch while a voltage is applied to the MEMS switch and/or while a current flows through the MEMS switch, also known as “hot switching.”

Embodiments described herein disclose a method of testing the hot switching capabilities of MEMS switches, along with example systems for testing a MEMS switch under hot switching conditions, referred to herein as a MEMS hot-switch testing apparatus. Embodiments provide for testing the pull-in and pull-off voltage, on-resistance and off resistance, and additionally provide for cycling the MEMS switch while a voltage is applied to at least one contact and/or while a current flows through the MEMS switch. Different methods of cycling the switch will be employed to evaluate the effects of hot switching during opening, closing, or both over the lifetime of the device.

As used herein, the term “pull-in voltage” refers to the voltage applied to a MEMS switch control gate that causes the switch to close (i.e., be conductive from input to output of the switch). As used herein, the term “pull-off voltage” refers to the voltage applied to a MEMS switch control gate that causes the switch to open (i.e., to be non-conductive from input to output of the switch). As used herein, the term “on-resistance” refers to the electrical resistance measured from the input to the output of the switch when the switch is closed, and “off resistance” refers to the electrical resistance measured from the input to the output of the switch when the switch is open.

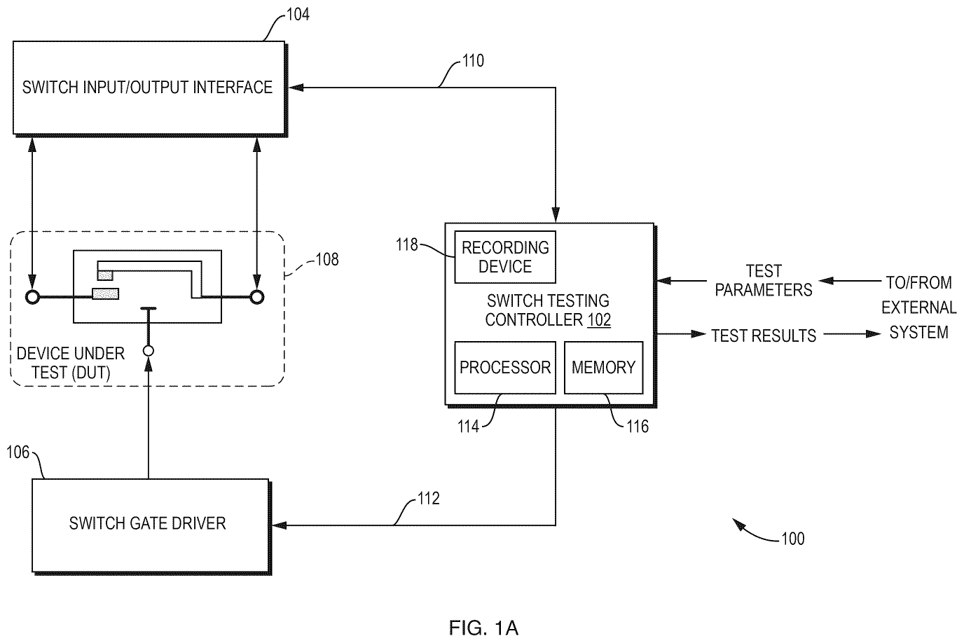

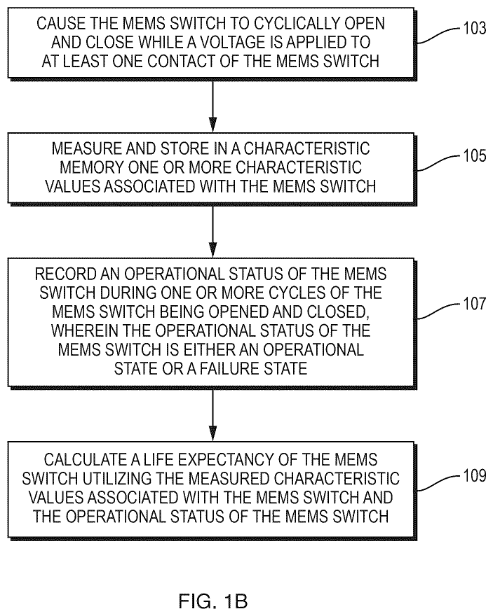

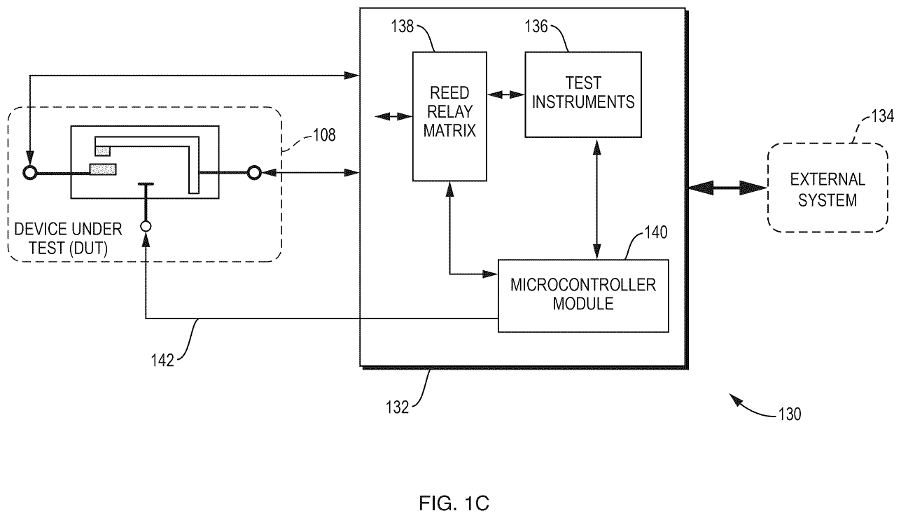

FIG. 1A shows a block diagram of an example MEMS hot-switch testing system, and FIG. 1B shows a flow diagram of example operation of a MEMS hot-switch testing system, according to an embodiment. As shown in FIG. 1A, the example MEMS hot-switch testing system and associated test circuit 100 which hosts the MEMS switch may include a switch testing controller 102, a switch input/output interface 104, and a switch gate driver 106. The test circuit “hosts” the MEMS switch, meaning that the circuit structure can accommodate the MEMS switch being removed and replaced for testing a plurality of MEMS switches. The switch input/output interface 104 and the switch gate driver 106 are each electrically coupled to one or more device under test (DUT) components 108, e.g., a MEMS switch to be evaluated under hot-switch conditions. In some embodiments, one or both of the switch input/output interface 104 and the switch gate driver 106 may be implemented by a reed switch matrix. The switch testing controller 102 may receive test parameters from an external source (e.g., from a test engineer or a test coordinating system) and may provide test results to the external source. The switch testing controller 102 may provide parameters and/or commands and/or timing information 110 to the switch input/output interface 104, which the switch input/output interface 104 uses to produce load, voltage, and current conditions to be applied to the inputs and outputs of DUT 108. The switch testing controller 102 may provide gate timing information 112 to the switch gate driver 106, which the switch gate driver 106 uses to produce a gate driving signal, at required gate voltage levels, to the gate of the DUT 108. The switch testing controller 102 may also be configured to include a recording device 118 configured to record at least one characteristic of the MEMS switch at one or more times while the control circuit causes the MEMS switch to be cyclically opened and closed.

As shown in FIG. 1A, the switch testing controller 102 of the example MEMS hot-switch testing system 100 may include a processor 114, and an instruction memory 116. The switch testing controller 102 may communicate with an external source such as a desktop computer. The processor 114 (for example, a CPU, a microcontroller, hardware state machine, etc.), and instruction memory 116 with computer code instructions stored thereon is configured, in an example embodiment, to cause the system to cyclically open and close 103 while a voltage is applied to at least one contact of the MEMS switch and/or a current flows through the MEMS switch, and measure 105 and store in a characteristic memory one or more characteristics associated with the MEMS hot-switch testing system, as shown in FIG. 1B. The characteristic memory may be implemented with a common data structure to that of the instruction memory 116, or it may be a separate memory independent from the instruction memory 116. The system also records 107 an operational status of the MEMS switch during one or more cycles of the MEMS switch being opened and closed, wherein the operational status of the MEMS switch is either an operational state or a failure state. The system then calculates 109 a life expectancy of the MEMS switch utilizing the measured characteristic values associated with the MEMS switch and the operational status of the MEMS switch.

FIG. 1C shows another example embodiment of a MEMS hot-switch testing system 130, which includes a primary testing module 132 and an external system 134 (e.g., a desktop or laptop computer). The primary testing module may comprise a set of test instruments 136, a relay matrix (e.g., a Reed relay matrix) 138, and a microcontroller module 140. The relay matrix 138 is configured to establish a variety of connections between the DUT 108 and the test instruments 136. The microcontroller module 140 is configured to control signals to the test instruments 136 and the relay matrix 138, and to generate gate signals 142 to the DUT 108. MEMS gate signals may require a voltage of over 50V, in which case a step-up amplifier (not shown) may be required to boost the gate control signal 142 that originates from the microcontroller module 140. In some cases, the MEMS device includes an internal voltage amplifier, so that only a digital level signal is required to open or close the MEMS switch. In this example embodiment, the external system 134 sends commands to the instruments 136 and the microcontroller module 140. External system 134 communication with the test instruments 136 may be accomplished with a test and measurement communication protocol (e.g., GPIB), and external system 134 communication with the microcontroller module 140 may be accomplished with a standard serial connection (e.g., USB). The external system 134 may send a command in the form of a string of characters to the microcontroller module 140, which parses the string and determines if the string represents a valid command, and what the command means if the string is valid. The microcontroller module 140 may control things such as turning relays on and off, turning CMOS switches on and off, and configuring the MEMS gate driver functionality.

The operational status of a properly functioning MEMS switch may be the MEMS switch being open when a control signal indicates that the MEMS switch should be open, and the MEMS switch being closed when a control signal indicates that the MEMS switch should be closed. Further, the operational status indicates an on-resistance of the MEMS switch being within a specified range when the control signal indicates that the MEMS switch should be closed, and the on-resistance of the MEMS switch being within a specified range when the control signal indicates that the MEMS switch should be open. If these conditions are not met, the system will return a failure state.

The example embodiments of the MEMS hot-switch testing apparatus described herein are directed to assessing the effect of actuating a voltage-controlled MEMS switch while a voltage exists between the input and the output of the MEMS switch and/or a current flows through the MEMS switch (i.e., a “hot” MEMS switch). Ideally, both the input and the output of the switch would be grounded (or both at a common voltage potential) during opening and closing of the switch, but this may not always be possible or desirable. In practical uses of the MEMS switch, a voltage drop across its input and output may be present during switching, which can cause arcing across the contacts. The arcing may damage the contacts and consequently reduce the lifetime of the MEMS switch. However, the precise effect of voltage, current, and load type on lifetime is not known, only that lifetime may be “reduced.” The example systems for testing a MEMS switch under hot switching conditions described herein exist to subject MEMS devices to different voltage and current levels with different resistive and capacitive loads, repeatedly opening and closing (referred to herein as “cycling”) the MEMS switch until failure. Failure is defined by the MEMS switch either failing to open (“stuck closed”) or failing to close (“stuck open”).

The example systems for the MEMS hot-switch testing system described herein may operate in one of two states: (i) a parametric testing state and (ii) a cycling state. At the start of the test and after a user-defined number of cycles (i.e., iterations of opening and closing of the MEMS switch), the test system measures the pull-in voltage, pull-off voltage, on-resistance, and off resistance of every channel of device under test (DUT). As used herein, a “channel” is a path through one MEMS switch from input to output. The example MEMS hot-switch testing system then stores this data in a file to be analyzed at the end of the test. This data may be plotted on a Weibull curve, which shows the expected probability of failure of a channel (or component, depending on the system) at any number of cycles, or on a lognormal distribution, or other appropriate data presentation technique.

During the cycling portion of the test, the MEMS switches of the DUTs are repeatedly opened and closed at a frequency up to, for example, 10 kHz. The frequency and duty cycle of the waveform can be adjusted according to user specifications and the load that is attached. For example, a large capacitive load cycles more slowly and the device is open longer than it is closed, since charging the large capacitor takes a relatively longer time. However, a purely resistive load can be cycled at, for example, 10 kHz with a 50% duty cycle.

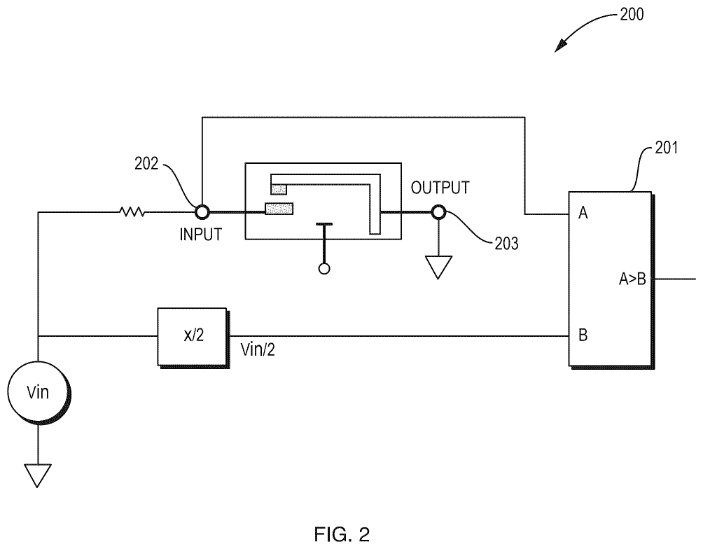

According to an embodiment, the MEMS hot-switch testing system 200 under hot switching conditions may also implement a “heartbeat” functionality, as shown in FIG. 2. By using a comparator 201 to compare the voltage applied at the input 202 of the switch to half of the voltage applied, the system can determine whether the switch is open or closed. For example, if the voltage at the input 201 is zero volts (0V), the switch is closed, since the input is tied to the output 203, which is grounded. If the voltage is the same as the voltage applied, the switch is open since the input and output are not connected. This allows the tester to test whether the switch is functional at every single cycle during the cycling portion of the test. If any channel is seen to be open when it should be closed (or vice versa), the exact cycle number is recorded and stored in a data file. This can be used to increase the resolution of the failure data: rather than measuring failures every one-million cycles, for example, the exact cycle at which the device failed will be recorded. In an example embodiment, the components shown in FIG. 2, except for the switch itself, may be implemented by the switch input/output interface 104 shown in FIG. 1A.

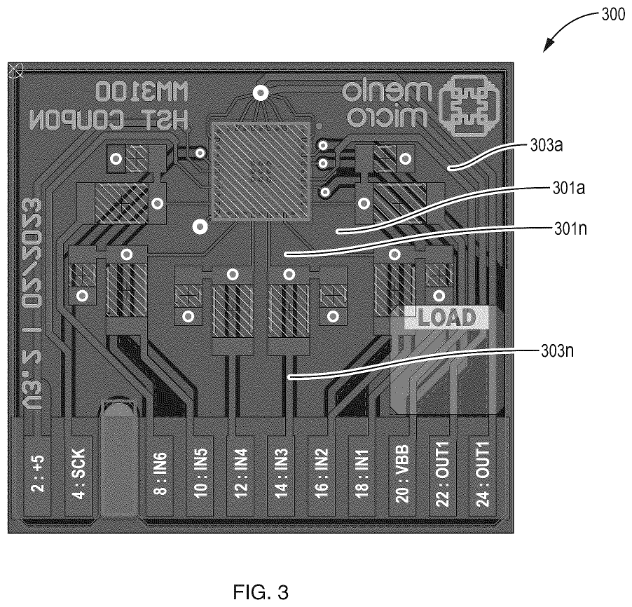

In an example embodiment, one or more daughter cards may be used to improve performance of the system for testing a MEMS switch under hot switching conditions, using the MEMS hot-switch testing apparatus. A daughter card is a small circuit board that can be easily connected to and disconnected from the main system circuit board or “motherboard.” The daughter card allows the system for testing a MEMS switch under hot switching conditions to be used with many different load conditions, which are combinations of resistance and capacitance connected to the input of the MEMS switch under test (DUT). By properly spacing the traces on the daughter cards, i.e., the material composition and the layout geometry of the test circuit, parasitic capacitance (and capacitive coupling) is reduced to levels that are insignificant compared to the load capacitance shown in FIG. 3. In some embodiments, the material composition and layout geometry of the test circuit may be designed specifically to maintain the parasitic capacitance at levels below a predetermined threshold. For example, the width and/or thickness of the traces, combined with a particular dielectric constant of the circuit board material upon which the trace is set, may affect the resulting parasitic capacitance.

FIG. 3 illustrates an example daughter card layout 300 showing how parasitic capacitance is reduced in the circuit design. The negative spaces 301a-n on the bottom layer, combined with a ground plane on the top layer, work to reduce capacitive coupling in the traces 303a-n. The material composition and the layout geometry of the test circuit, i.e., the length of the traces being such that the distance between the device and the capacitors is small, helps reduce parasitic inductance in the traces. In some embodiments, the material composition and layout geometry of the test circuit may be designed specifically to maintain the parasitic inductance at levels below a predetermined threshold. For example, the width, length, and/or thickness of the traces may affect the resulting parasitic inductance.

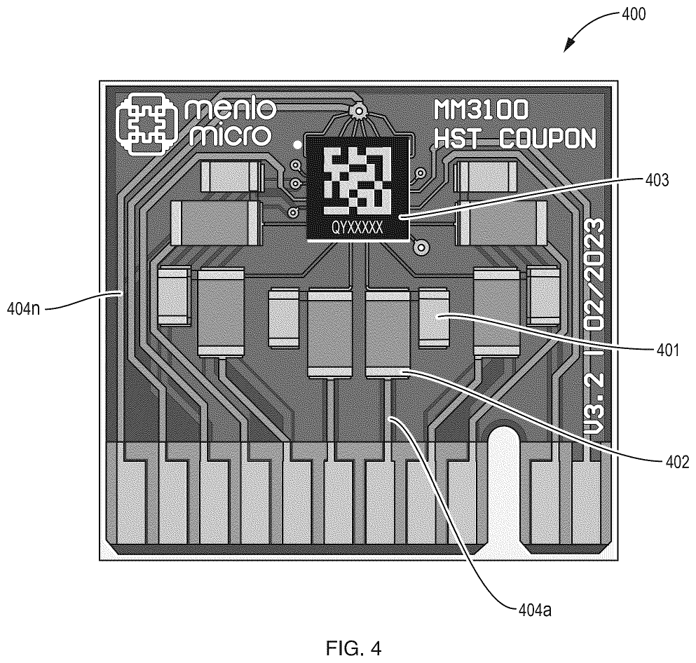

FIG. 4 shows a 3D rendering of an example daughter card 400 illustrating the placement of load components, such as load capacitors 401 and load resistors 402, relative to the device under test 403. Placing the capacitors and resistors close to the MEMS device allows the length of the trace 404a-n between the load components and the MEMS device to be relatively short, which reduces the parasitic inductance and limits the inductive voltage spikes that may occur when the MEMS switch opens and closes during cycling. Therefore, the material composition and the layout geometry of the test circuit reduces the parasitic inductance and limits the inductive voltage spikes that may occur when the MEMS switch opens and closes during cycling.

In an example embodiment of a system for testing a MEMS switch under hot switching conditions, the load components were connected via approximately 4-inch-long wires on a breadboard, resulting in capacitive coupling between the traces. This arrangement may result in substantial spikes in voltage, which may be large enough to damage other parts of the circuit.

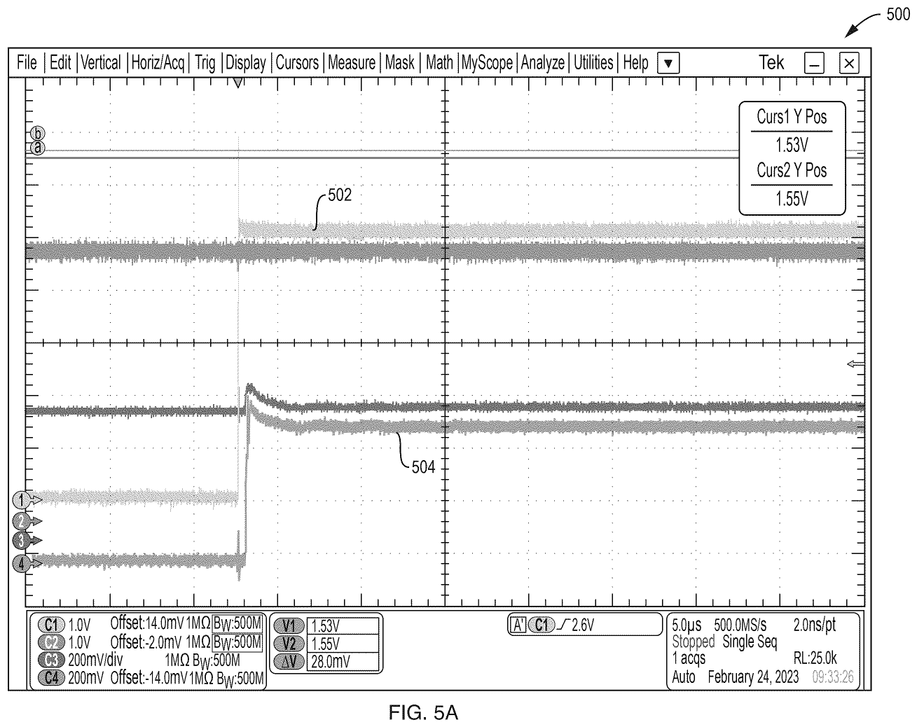

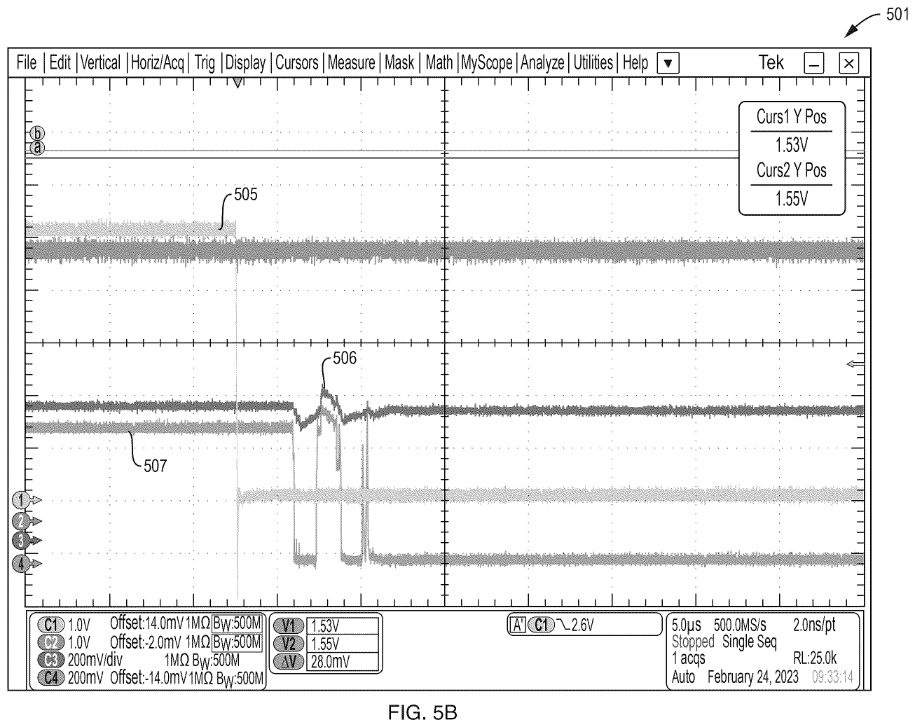

FIG. 5A show an oscilloscope readout 500 of the waveform showing the capacitive coupling between the channels while the MEMS device is opening. In this case the gate control line 502 (which controls whether the gate is open or closed) is active, and FIG. 5A demonstrates that additional channel 504 (the channel being controlled) also experiences capacitive coupling. The additional channel 504 measures then voltage across the active channel, while the gate control line 502 controls that channel. This is an example of the capacitive coupling that may occur with the within a daughter card that has shorter more isolated traces.

Reducing these parasitic electrical characteristics is desirable because these spikes can subject the DUT to unnecessary stress and likely reduce its lifetime, which may cause that load condition to appear harsher than it actually is. The example embodiment shown in FIG. 4 exhibited inductive spikes on the order of 50-100 mV, as shown in FIG. 5B. The additional oscilloscope readout 501 shows significantly smaller inductive spikes and capacitive coupling when the test is turned on with the shorter traces on the board. When the control line 505 is active, FIG. 5B shows that the adjacent channel 506 (measured to show the capacitive coupling) and the main channel 507 also experience capacitive coupling when the main channel 507 is turned on. This reduction in capacitive coupling is due to the increased spacing and the addition of a ground plane between traces, i.c., the layout geometry. The reduction in inductance is due to the shortening of the traces and the placement of the load components close to the DUT, i.e., the layout geometry.

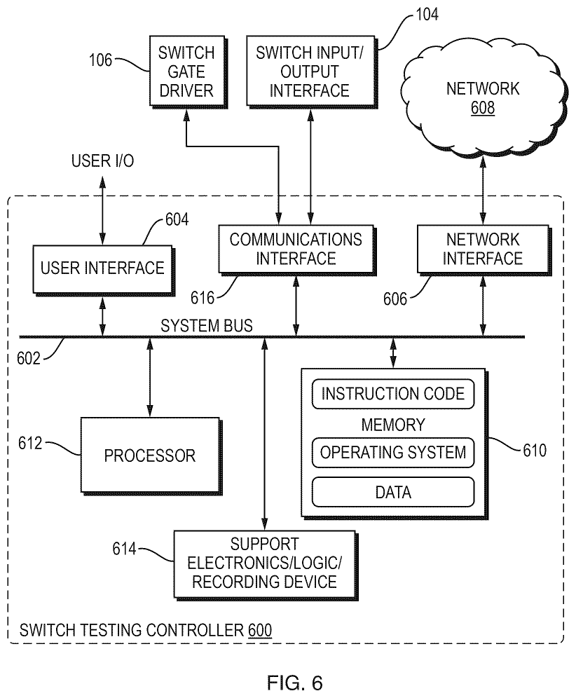

FIG. 6 is a diagram of an example internal structure of a processing system 600 that may be used to implement one or more of the embodiments herein. Each processing system 600 contains a system bus 602, where a bus is a set of hardware lines used for data transfer among the components of a computer or processing system. The system bus 602 is essentially a shared conduit that connects different components of a processing system (e.g., processor, disk storage, memory, input/output ports, network ports, etc.) that enables the transfer of information between the components.

Attached to the system bus 602 is a user I/O device interface 604 for connecting various input and output devices (e.g., keyboard, mouse, displays, printers, speakers, etc.) to the processing system 600. A network interface 606 allows the computer to connect to various other devices attached to a network 608. Memory 610 provides volatile and non-volatile storage for information such as computer software instructions used to implement one or more of the embodiments of the present invention described herein, for data generated internally and for data received from sources external to the processing system 600.

A central processor unit 612 is also attached to the system bus 602 and provides for the execution of computer instructions stored in memory 610. The system may also include support electronics/logic 614, and a communications interface 616. The communications interface may comprise the interface to the switch gate driver 106 and the switch input/output interface 104 described with reference to FIG. 1.

In one embodiment, the information stored in memory 610 may comprise a computer program product, such that the memory 610 may comprise a non-transitory computer-readable medium (e.g., a removable storage medium such as one or more DVD-ROM's, CD-ROM's, diskettes, tapes, and other such media known in the art) that provides at least a portion of the software instructions for the invention system. The computer program product can be installed by any suitable software installation procedure, as is well known in the art. In another embodiment, at least a portion of the software instructions may also be downloaded over a cable communication and/or wireless connection.

While example embodiments have been particularly shown and described, it will be understood by those skilled in the art that various changes in form and details may be made therein without departing from the scope of the embodiments encompassed or contemplated herein.

What is claimed is:

1. A system for testing a micro-electromechanical-system (MEMS) switch under hot switching conditions, the system comprising:
a processor; and
an instruction memory with computer code instructions stored thereon, the processor and the memory with computer code instructions configured to cause the system to:
cause the MEMS switch to cyclically open and close while a voltage is applied to at least one contact of the MEMS switch;
measure and store in a characteristic memory one or more characteristic values associated with the MEMS switch during the cyclical open and closing; and
record an operational status of the MEMS switch during one or more cycles of the MEMS switch being opened and closed, wherein the operational status of the MEMS switch is either an operational state or a failure state;
the processor and instruction memory with computer code instructions stored thereon further configured to:
calculate a life expectancy of the MEMS switch utilizing the measured characteristic values associated with the MEMS switch and the operational status of the MEMS switch.

2. The system of claim 1, wherein the one or more characteristic values comprises a pull-in voltage, pull-off voltage, on-resistance, and/or off-resistance of at least one channel of the MEMS switch.

3. The system of claim 1, further comprising a test circuit that: (i) hosts the MEMS switch, and (ii) is operatively coupled to the processor to receive one or more control signals from the processor for controlling the MEMS switch and to provide one or more characteristic values associated with the MEMS switch to the processor.

4. The system of claim 3, wherein a material composition and a layout geometry of the test circuit are configured to maintain parasitic inductance below a predetermined inductance threshold and maintain parasitic capacitance below a predetermined capacitance threshold.

5. The system of claim 4, wherein the material composition and a layout geometry of the test circuit is further configured to provide appropriate spacing and/or insulation to reduce parasitic inductance and/or parasitic capacitance.

6. The system of claim 1, wherein the computer code instructions are further configured to cause the system to measure the one or more characteristic values prior to the MEMS switch being cyclically opened and closed and/or after the operational status indicates a failure state of the MEMS switch.

7. The system of claim 6, wherein the failure state is determined by any one of the MEMS switches failing to open or failing to close, any one of a parametric value being outside of a manufacturer specified value for the MEMS switch, or any combination thereof.

8. The system of claim 1, wherein the operational status comprises:
the MEMS switch being open when a control signal indicates that the MEMS switch should be open, and the MEMS switch being closed when a control signal indicates that the MEMS switch should be closed; and
an on-resistance of the MEMS switch being within a specified range when the control signal indicates that the MEMS switch should be closed, and the on-resistance of the MEMS switch being within a specified range when the control signal indicates that the MEMS switch should be open.

9. The system of claim 1, wherein the cyclically opening and closing the MEMS switch further comprises cycling the MEMS switch through a predetermined number of open-to-close and close-to-open cycles.

10. The system of claim 1, wherein the system is configured to measure, test, and record repeatedly until the MEMS switch indicates a failure state.

11. The system of claim 8, wherein if the operational status is not met, the system returns a failure state.

12. The system of claim 1, wherein the voltage is non-zero.

13. The system of claim 1, wherein the computer code instructions are further configured to cause the system to:
apply a known first voltage through a load resistor to an input of the MEMS switch;
measure a second voltage at the input of the MEMS switch;
compare a reference voltage that is greater than zero volts and less than the known first voltage to the second voltage; and
indicate that the MEMS switch is open when a comparison shows the second voltage is above the known first voltage, or the MEMS switch is closed when the second voltage is below the known first known voltage, based on the comparison of the known first voltage and the second voltage.

14. The system of claim 1, wherein the system is further configured to adjust a frequency of the cyclical open and cyclical close of the MEMS switch based on electrical characteristics of an electrical load.

15. The system of claim 1, wherein the system is further configured to adjust a duty cycle of the cyclical open and cyclical close of the MEMS switch based on electrical characteristics of an electrical load.

16. The system of claim 3, further comprising a reed relay matrix configured to selectively couple one or more test instruments to the MEMS switch.

17. The system of claim 1, wherein the instruction memory and the characteristic memory share a common physical memory space.

18. A system for testing a micro-electro-mechanical-system (MEMS) switch under hot switching conditions, the system comprising:
a control circuit configured to cause the MEMS switch to be cyclically opened and closed while a voltage is applied to at least one contact of the MEMS switch;
a measurement device configured to measure at least one characteristic of the MEMS switch; and
a recording device configured to record the at least one characteristic of the MEMS switch at one or more times while the control circuit causes the MEMS switch to be cyclically opened and closed.

19. A method of testing a micro-electromechanical-system (MEMS) switch under hot switching conditions, the method comprising:
causing the MEMS switch to cyclically open and close while a voltage is applied to at least one contact of the MEMS switch; and
measuring and storing in a characteristic memory one or more characteristic values associated with the MEMS switch during the cyclical open and closing; and
recording an operational status of the MEMS switch during one or more cycles of the MEMS switch being opened and closed, wherein the operational status of the MEMS switch is either an operational state or a failure state; and
calculating a life expectancy of the MEMS switch utilizing the measured characteristic values associated with the MEMS switch and the operational status of the MEMS switch.
